(19) United States
(12) Patent Application Publication
(10) Pub. No.: US 2009/0053617 A1
(43) Pub. Date: Feb. 26, 2009

(54) HOLOGRAPHIC RECORDING MEDIUM

(75) Inventor: Makoto KAMO, Ashigarakami-Gun (JP)

Correspondence Address: SUGHRUE MION, PLLC, 2100 PENNSYLVANIA AVENUE, N.W., SUITE 800, WASHINGTON, DC, 20037, US

(73) Assignee: Fujifilm Corporation, Tokyo (JP)

(21) Appl. No.: 12/190,846

(22) Filed: Aug. 13, 2008

(30) Foreign Application Priority Data
Aug. 22, 2007 (JP) 2007-215725

(51) Int. Cl. G03F 7/00

(52) U.S. Cl. 430/2

(57) ABSTRACT

A holographic recording medium includes: a recording layer in which is recordable an interference pattern formed by interference of a plurality of laser beams; a pair of substrates between which is arranged the recording layer; and a spacer positioned between the substrates so as to cover an outer perimetrical surface of the recording layer. Each substrate and the spacer have mating faces at which the substrate and the spacer are interengageable and bonded together with an adhesive agent. A cross-sectionally recessed portion is formed in the mating face of one of the substrate and the spacer, whereas a corresponding cross-sectionally protruding portion is formed on the mating face of the other one of the spacer and the substrate, allowing one mating face to be fitted into another.

### CROSS REFERENCE TO RELATED APPLICATION

This application claims the foreign priority benefit under Title 35, United States Code, §119(a)-(d) of Japanese Patent Application No. 2007-215725 filed on Aug. 22, 2007 in the Japan Patent Office, the disclosure of which is herein incorporated by reference in its entirety.

### BACKGROUND OF THE INVENTION

The present invention relates to a holographic recording medium in which data are recorded using interference of light waves.

In recent years, development has been carried out for holographic recording media with a recording layer in the shape of a thick film, in which an extremely large amount of data are recorded as interference patterns using interference of light waves. In general, a holographic recording medium comprises a pair of substrates, and a recording layer positioned between the substrates.

Such a holographic recording medium has an extremely thick recording layer when compared with a recording layer of a CD (Compact Disc) or a DVD (Digital Versatile Disc), and information is three-dimensionally recorded in the recording layer. Therefore, a volume change in the recording layer by expansion or contraction, i.e., a warpage (curl) of the disc caused by a difference in the volumetric expansion or contraction rate between the substrate and the recording layer, will affect the quality of the medium more seriously than other media such as a CD and a DVD. The volumetric expansion or contraction of the recording layer may occur for various reasons such as a change in the material at the time of data recording, expansion or contraction resulting from a temperature change, and expansion or contraction resulting from moisture and gas entering or volatilized from the recording layer.

In view of the above drawback, for example, Japanese Laid-open patent Publication No. 2001-5368 and WO02/084410 (also published as Japanese Translation of PCT International Application No. 2004-524583) disclose a holographic recording medium in which is provided a ring-shaped spacer around the outer peripheral surface of the recording layer, and a ring-shaped inner spacer around the inner peripheral surface of the recording layer for the recording layer that is shaped like a disc having a center opening. These spacers and the recording layer are positioned between a pair of substrates with the spacers and the substrates being bonded together with an adhesive agent, so as to prevent moisture or gas from entering the recording layer from outside of the holographic recording medium.

Further, Japanese Laid-open Patent Publication No. 2005-17589 discloses a holographic recording medium consisting of a pair of substrates and a recording layer. In this holographic recording medium, the recording layer may be made of a recording material having a self-sealing property as disclosed in WO 03/023519 also published as Japanese Translation of PCT International Application No. 2005-502918. This recording material changes to a material which can restrict or prevent an entry of water, etc. when it is exposed to moisture. An entry of water, etc. into the recording layer can also be prevented by applying a sealing agent around the periphery of the recording layer so as to form a sealing portion.

However, in the prior art configuration where a sealing portion (including a sealed portion provided by the self-sealing property) is formed around the recording layer, if the sealing portion is damaged by contacting with other structural elements and being abraded, the recording layer is exposed and deteriorates in its sealing performance. This leads to a difficulty in long-term storage of the holographic recording medium.

In the other prior art configuration where a spacer is provided around the recording layer, the bonding surface (sealing portion) between the spacer and the substrate is exposed only at the outer periphery; the other parts are positioned inside the holographic recording medium and the sealing portion is free from damaging. However, in order to prevent an entry of moisture, etc. from the bonding surface between the spacer and the substrate, it is necessary to choose an adhesive agent which provides adhesiveness as well as a moisture-proof property, in particular an adhesive agent with highly moisture-proof property. This will narrow the choice of the adhesive agent to be used and therefore end in complication of the choice of the adhesive agent upon manufacture of the holographic recording medium.

In view of the above, the present invention seeks to provide a holographic recording medium, in which the choice of the adhesive agent to be used can be easily made and the holographic recording medium can be stored over an extended period of time.

### SUMMARY OF THE INVENTION

According to one aspect of the present invention, there is provided a holographic recording medium which includes: a recording layer in which is recordable an interference pattern formed by interference of a plurality of laser beams; a pair of substrates between which is arranged the recording layer; and a spacer positioned between the substrates so as to cover an outer perimetrical surface of the recording layer. In this holographic recording medium, each substrate and the spacer have mating faces at which the substrate and the spacer are interengageable and bonded together with an adhesive agent, and a cross-sectionally recessed portion is formed in the mating face of one of the substrate and the spacer, whereas a corresponding cross-sectionally protruding portion is formed on the mating face of the other one of the spacer and the substrate, allowing one mating face to be fitted into another.

The aforementioned holographic recording medium may further comprise an inner spacer positioned between the substrates so as to cover an inner peripheral surface of the recording layer which is shaped like a disc having a center opening. Each substrate and the inner spacer have mating faces at which the substrate and the inner spacer are interengageable and bonded together with an adhesive agent, and a cross-sectionally recessed portion is formed in the mating face of one of the substrate and the inner spacer, whereas a corresponding cross-sectionally protruding portion is formed on the mating face of the other one of the inner spacer and the substrate, allowing one mating face to be fitted into another.

With these configurations of the holographic recording medium according to the present invention, because the cross-sectionally recessed portion and the corresponding cross-sectionally protruding portion are formed in and on the mating faces which are to be interengageable and bonded together with an adhesive agent, the length of a possible moisture-permeation passage (i.e., interface between the mating faces through which moisture, etc. would possibly enter the recording layer) can be extended so that moisture, etc. can hardly enter the recording layer. Therefore, the holographic recording medium can be stored over an extended period of time even if the choice of the adhesive agent is not so strictly made.

In the aforementioned holographic recording medium, the cross-sectionally recessed portion and the corresponding cross-sectionally protruding portion may comprise at least one ring-shaped peripheral groove and at least one corresponding ridge formed in and on the mating faces of the substrate and the spacer along the outer perimetrical surface of the recording layer which is shaped like a disc. In the case where the inner spacer is provided, the cross-sectionally recessed portion and the corresponding cross-sectionally protruding portion formed in and on the mating faces of the substrate and the inner spacer may comprise at least one ring-shaped peripheral groove and at least one corresponding ridge along the inner peripheral surface of the recording layer.

As an alternative embodiment, the cross-sectionally recessed portion and the corresponding cross-sectionally protruding portion may comprise a spiral groove and a corresponding spiral ridge formed in and on the mating faces of the substrate and the spacer along the outer perimetrical surface of the recording layer which is shaped like a disc. In the case where the inner spacer is provided, the cross-sectionally recessed portion and the corresponding cross-sectionally protruding portion formed in and on the mating faces of the substrate and the inner spacer may comprise a spiral groove and a corresponding spiral ridge along the inner peripheral surface of the recording layer.

With these configurations of the holographic recording medium, moisture, etc. entering the recording layer from any directions have to pass through the possible moisture-permeation passage which is bent by the cross-sectionally recessed portion and the corresponding cross-sectionally protruding portion. Therefore, an entry of moisture, etc. can be effectively restricted.

In the aforementioned holographic recording medium, the spacer and the inner spacer if any may be integral with one of the pair of substrates.

With this configuration of the holographic recording medium, only a pair of cross-sectionally recessed portion and corresponding cross-sectionally protruding portion, which are to be interengageable and bonded together with an adhesive agent, is formed in and on the mating faces between the spacer that is integrally formed on one of the substrates and the other substrate. Namely, the possible moisture-permeation passage is formed on one layer that is the bonding surface between the spacer and the other substrate, so that an entry of moisture, etc. can be effectively restricted.

According to another aspect of the present invention, there is provided a holographic recording medium which includes: a recording layer in which is recordable an interference pattern formed by interference of a plurality of laser beams; and a pair of substrates between which is arranged the recording layer. In this holographic recording medium, each substrate has an outer perimetrical protrusion extending toward the other substrate and surrounding an outer perimetrical surface of the recording layer, and each outer perimetrical protrusion has a mating face at which the pair of substrates are interengageable and bonded together with an adhesive agent. A cross-sectionally recessed portion is formed in the mating face of the outer perimetrical protrusion of one substrate, whereas a corresponding cross-sectionally protruding portion is formed on the mating face of the outer peripheral protrusion of the other substrate, allowing one mating face to be fitted into another.

In the aforementioned holographic recording medium, each substrate has an inner peripheral protrusion extending toward the other substrate and surrounding an inner peripheral surface of the recording layer, and each inner peripheral protrusion has a mating face at which the pair of substrates are interengageable and bonded together with an adhesive agent. A cross-sectionally recessed portion is formed in the mating face of the inner peripheral protrusion of one substrate, whereas a corresponding cross-sectionally protruding portion is formed on the mating face of the inner peripheral protrusion of the other substrate, allowing one mating face to be fitted into another.

With these configurations of the holographic recording medium according to the present invention, because the cross-sectionally recessed portion and the corresponding cross-sectionally protruding portion are formed in and on the mating faces which are to be interengageable and bonded together with an adhesive agent, the length of a possible moisture-permeation passage (i.e., interface between the mating faces through which moisture, etc. would possibly enter the recording layer) can be extended so that moisture, etc. can hardly enter the recording layer. The possible moisture-permeation passage is formed on one layer that is the bonding surface between the substrates, so that an entry of moisture, etc. can be effectively restricted. Therefore, the holographic recording medium can be stored over an extended period of time even if the choice of the adhesive agent is not so strictly made.

In the aforementioned holographic recording medium, the cross-sectionally recessed portion and the corresponding cross-sectionally protruding portion at the outer perimetrical protrusions and at the inner peripheral protrusions if any of the pair of substrates may comprise at least one ring-shaped peripheral groove and at least one corresponding ridge formed in and on the mating faces of the pair of substrates along the outer perimetrical surface and the inner peripheral surface of the recording layer which is shaped like a disc having a center opening.

As an alternative embodiment, the cross-sectionally recessed portion and the corresponding cross-sectionally protruding portion at the outer perimetrical protrusions and at the inner peripheral protrusions if any of the pair of substrates may comprise a spiral groove and a corresponding spiral ridge formed in and on the mating faces of the pair of substrates along the outer perimetrical surface and the inner peripheral surface of the recording layer which is shaped like a disc having a center opening.

With these configurations of the holographic recording medium, moisture, etc. entering the recording layer from any directions have to pass through the possible moisture-permeation passage which is bent by the cross-sectionally recessed portion and the corresponding cross-sectionally protruding portion. Therefore, an entry of moisture, etc. can be effectively restricted.

According to the present invention, the cross-sectionally recessed portion and the corresponding cross-sectionally protruding portion are formed in and on the mating faces which are to be interengageable and bonded together with an adhesive agent, so that moisture, etc. can hardly enter the recording layer. Therefore, the choice of the adhesive agent to be used can be easily made and the holographic recording medium can be stored over an extended period of time.

### BRIEF DESCRIPTION OF THE DRAWINGS

Other objects and aspects of the present invention will become more apparent by describing in detail illustrative, non-limiting embodiments thereof with reference to the accompanying drawings, in which:

FIG. 1 is an exploded perspective view illustrating a holographic recording medium according to one embodiment of the present invention;

FIG. 2A is a cross-sectional view showing a half of the structure of the holographic recording medium of FIG. 1;

FIG. 2B is an enlarged cross-section showing details of the structure around an outer spacer;

FIG. 2C is an enlarged cross-section showing details of the structure around an inner spacer;

FIG. 3A is a cross-sectional view explaining a state in which moisture enters a conventional holographic recording medium;

FIG. 3B is a cross-sectional view explaining a state in which moisture enters a holographic recording medium according to one embodiment of the present invention;

FIG. 4 is a cross-sectional view showing an embodiment in which a spacer is integrally formed with one of a pair of substrates;

FIG. 5 is a cross-sectional view showing an embodiment in which each substrate has an outer peripheral protrusion and an inner peripheral protrusion extending from the outer peripheral surface and the inner peripheral surface of the substrate;

FIG. 6A is a plan view showing spiral grooves which are modifications of the cross-sectionally recessed portions; and

FIG. 6B is a plan view showing a plurality of semi-spherical recesses arranged at random.

### DETAILED DESCRIPTION OF THE INVENTION

With reference to the accompanying drawings, preferred embodiments of the present invention will be described below.

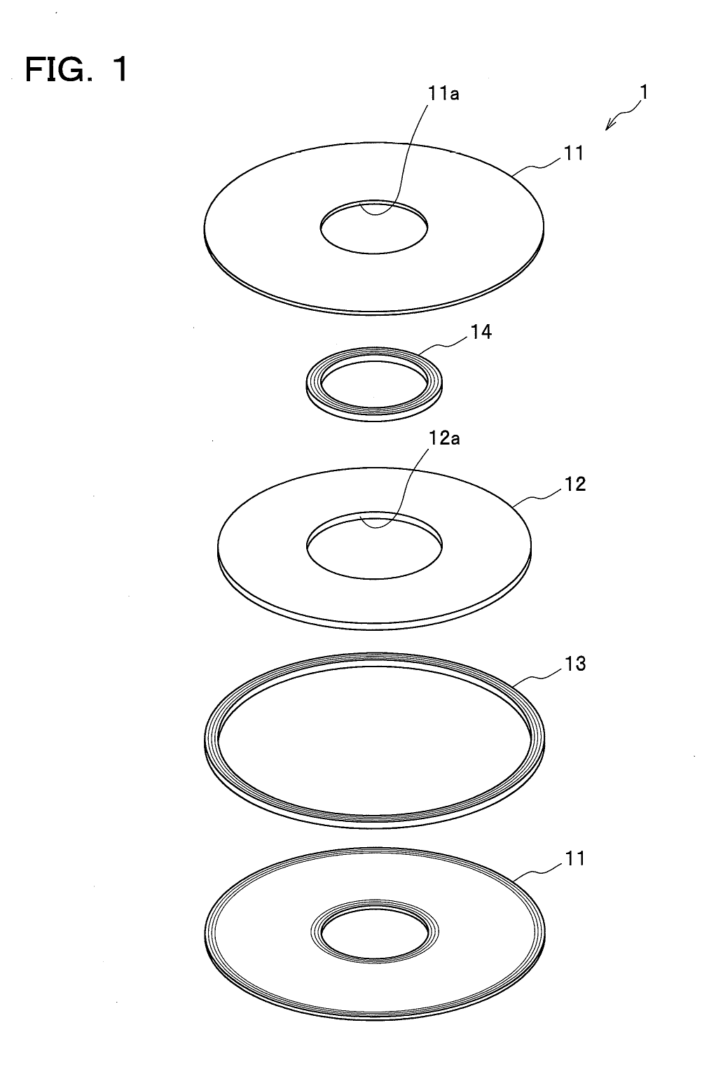

As seen in FIG. 1, a holographic recording medium 1 includes a pair of substrates 11, a recording layer 12 held between the substrates 11, an outer spacer 13, and an inner spacer 14.

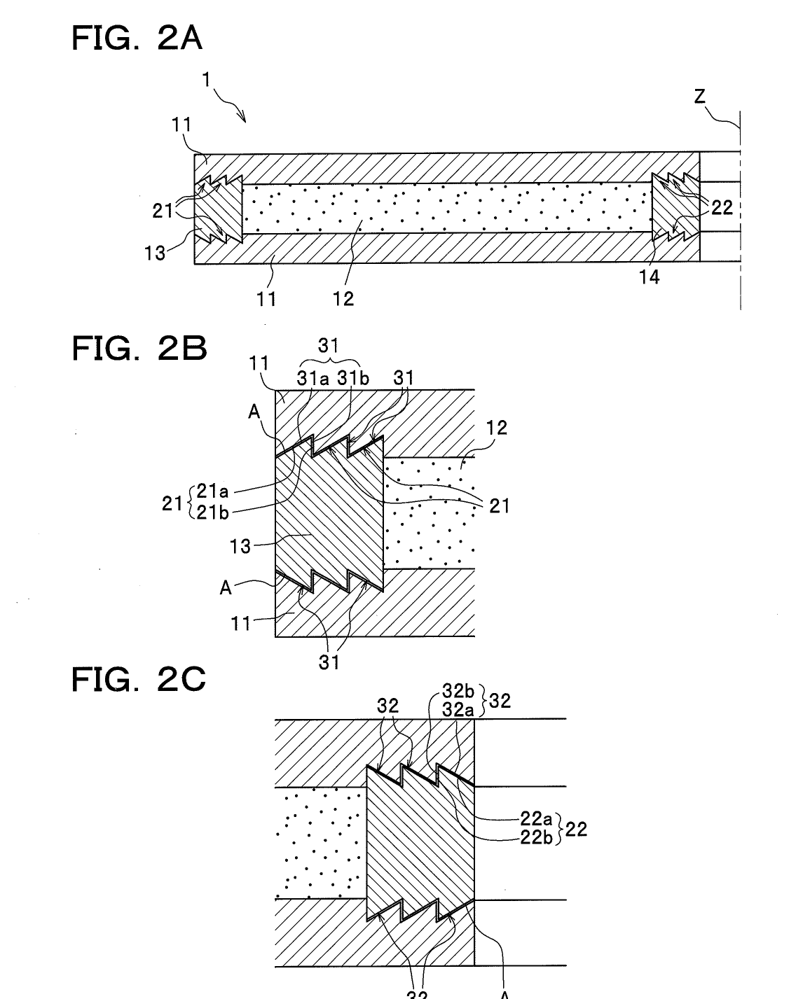

Each substrate 11 functions as a layer for protecting an upper surface or a lower surface of the recording layer 12. The substrate is made of a material which allows transmission of a laser beam having a wavelength of approximately 532 nm, for example. Herein, the term “laser beam” indicates a laser beam which is used as either one of a signal beam, a reference beam, and a readout beam. The substrate 11 is shaped like a disc having a center opening 11a. As best seen in FIG. 2A, the substrate 11 has a plurality of ring-shaped (continuous) peripheral grooves 21 at an outer peripheral portion on the lower or upper surface thereof facing the recording layer 12, and a plurality of ring-shaped (continuous) peripheral grooves 22 at an inner peripheral portion on the lower or upper surface thereof facing the recording layer 12. In the illustrated embodiment, each of the outer grooves 21 and the inner grooves 22 have three ring-shaped peripheral grooves arranged concentrically with respect to the center of the holographic recording medium 1, and they are recessed in a direction away from the recording layer 12. To be more specific, as seen in FIG. 2B, the outer grooves 21 are formed of tilted surfaces 21a which tilt away from the recording layer 12 toward the radially inner direction of the holographic recording medium 1, and vertical walls 21b extending parallel to a rotation axis Z of the holographic recording medium 1. Similarly, as seen in FIG. 2C, the inner grooves 22 are formed of tilted surfaces 22a which tilt away from the recording layer 12 toward the radially outer direction of the holographic recording medium 1, and vertical walls 22b extending parallel to the rotation axis Z of the holographic recording medium 1. For example, the outer grooves 21 and the inner grooves 22 can be formed by injection molding so that a shape of a mold can be transferred into the grooves. The outer grooves 21 and the inner grooves 22 can also be formed by machining with a lathe.

Any known materials may be used for producing the substrate 11 as long as they are sufficiently transparent to light in the wavelength range of the beam to be used. For example, the substrate 11 is made of a material such as glass, ceramic, and resin. However, resin is particularly preferable in terms of moldability and cost. Specific examples of the resin may include polycarbonate resins, acrylic resins, epoxy resins, polystyrene resins, acrylonitrile-styrene copolymers, polyethylene resins, polypropylene resins, polycyclo-olefin resins, silicon resins, ABS resins, and urethane resins. Of these resins, polycarbonate resins, acrylic resins, and polycyclo-olefin resins are particularly preferable in terms of moldability, optical characteristics, and cost.

Various processing or finishing can be applied to the substrate 11 for additional functions; for example, a reflective film, a selective reflection film, an antireflection film, a deposited film for improving sealing, an evaporated film for improving barrier properties, a gap layer, an information layer with servo signals for focusing/tracking servos, a selective absorption layer, and a selective transmission film can be additionally provided. The gap layer indicates a transparent layer to provide a gap between the surface of the substrate and the above additional functional layer in the case where at least one of the substrates 11 includes the additional functional layer inside the substrate.

The substrate 11 is prepared, for example, by injection molding. The thickness of the substrate 11 is in the range of 0.1-5 mm, and more preferably in the range of 0.3-2 mm. If the thickness of the substrate 11 is less than 0.1 mm, it may be difficult for the disc to keep its own shape without deformation during the storage of the disc. On the other hand, if the thickness of the substrate 11 is more than 5 mm, the whole weight of the disc becomes so large that an excessive load will be applied to a drive motor or a spindle.

The recording layer 12 reacts by irradiation with a plurality of laser beams (i.e., interference of the signal beam and the reference beam), and records data as an interference pattern. As seen in FIG. 1, the recording layer 12 is molded and cured in advance into the shape of a disc having a center opening 12a. The recording layer 12 is formed such that the outer peripheral surface and the inner peripheral surface thereof are positioned more inwardly than the outer peripheral surface and the inner peripheral surface of the substrate 11 by the distances corresponding to the width (length in the radial direction) of the outer spacer 13 and the width of the inner spacer 14, respectively.

Any known materials may be used as a material for the recording layer 12, and in accordance with application purposes, an appropriate material may be chosen. For example, (1) photopolymers causing a polymerization reaction in response to light irradiation and being highly polymerized, (2) photorefractive materials exhibiting a photorefractive effect (space charge distribution is changed by irradiation with light and the refractive index is modulated), (3) photochromic materials whose molecules are isomerized by irradiation with light and the refractive index thereof is modulated, (4) inorganic materials such as lithium niobate and barium titanate, and (5) chalcogen materials are available.

The recording layer 12 may be prepared by various conventional methods in accordance with materials to be used. In the case where the recording layer 12 is formed on the substrate, for example, a vapor deposition method, a coating method, an LB method, a printing method, and a transfer method are preferable. Further, in the case where the recording layer 12 alone is formed without combination of the other layers, a crystal growth method, a wet film-forming method, a stretching method, and an injection molding method are available. Of these methods, the coating method using the materials (1), (2) and (3) above, the wet film-forming method, and the injection molding method are preferable, and in particular, the wet film-forming method and the injection molding method (especially, liquid injection molding (LIM) method) are more preferable.

The thickness of the recording layer 12 is not limited and can be selected appropriately in accordance with purposes of the recording layer 12. The thickness of the recording layer 12 is preferably in the range of 1-1,000 μm, and more preferably in the range of 100-700 μm.

The outer spacer 13 is formed to have a thickness substantially equal to the thickness of the recording layer 12. The outer peripheral surface of the outer spacer 13 has substantially the same diameter as the outer peripheral surface of the substrate 11, and the inner peripheral surface of the outer spacer 13 has substantially the same diameter as the outer peripheral surface of the recording layer 12. The outer spacer 13 is positioned between the pair of substrates 11 in such a manner as to surround the outer peripheral surface of the recording layer 12. As best seen in FIG. 2B, three continuous ring-shaped peripheral ridges 31 to be fitted into the corresponding ring-shaped peripheral grooves 21 formed in the substrate 11 are arranged concentrically with respect to the center of the holographic recording medium 1 respectively on the upper surface and the lower surface of the outer spacer 13 (mating faces with the substrates 11). To be more specific, the ring-shaped peripheral ridges 31 are formed of tilted surfaces 31a which tilt and extend toward the substrate 11 in the radially inner direction of the holographic recording medium 1, and vertical walls 31b extending parallel to the axis of the holographic recording medium 1.

The inner spacer 14 is formed to have a thickness substantially equal to the thickness of the recording layer 12. The outer peripheral surface of the inner spacer 14 has substantially the same diameter as the inner peripheral surface of the recording layer 12, and the inner peripheral surface of the inner spacer 14 has substantially the same diameter as the inner peripheral surface of the substrate 11. The inner spacer 14 is positioned between the pair of substrates 11 in such a manner as to surround the inner peripheral surface of the recording layer 12. As best seen in FIG. 2C, three continuous ring-shaped peripheral ridges 32 to be fitted into the corresponding ring-shaped peripheral grooves 22 formed in the substrate 11 are provided respectively on the upper surface and the lower surface of the inner spacer 14 (mating faces with the substrates 11) and arranged in the radial direction of the holographic recording medium 1. To be more specific, the ring-shaped peripheral ridges 32 are formed of tilted surfaces 32a which tilt and extend toward the substrate 11 in the radially outer direction of the holographic recording medium 1, and vertical walls 32b extending parallel to the axis of the holographic recording medium 1.

For example, the outer ring-shaped peripheral ridges 31 and the inner ring-shaped peripheral ridges 32 can be formed by injection molding so that a shape of a mold can be transferred into the ridges. These ring-shaped peripheral ridges 31, 32 can also be formed by machining with a lathe.

The outer spacer 13 and the inner spacer 14 may be made of any known materials such as used for the substrate 11 as described above. These materials may comprise glass, ceramic, and resin. However, resin is particularly preferable in terms of moldability and cost. Specific examples of the resin may include polycarbonate resins, acrylic resins, epoxy resins, polystyrene resins, acrylonitrile-styrene copolymers, polyethylene resins, polypropylene resins, polycyclo-olefin resins, silicon resins, ABS resins, and urethane resins. Unlike the substrates 11, the spacers 13, 14 may be transparent or colored, or provide light-screening characteristics. However, acrylic resins, epoxy resins, polycyclo-olefin resins, and polyurethane resins are particularly preferable in terms of its strength.

The pair of substrates 11, the outer spacer 13, and the inner spacer 14 are bonded together using an adhesive agent A. To be more specific, the adhesive agent A is applied on the mating faces between the pair of substrates 11, the outer spacer 13, and the inner spacer 14 (i.e., tilted surfaces 21a, 22a, 31a, 32a, and vertical walls 21b, 22b, 31b, 32b) so that adhesive layers are formed therebetween.

Applying the adhesive agent between the pair of substrates 11 and the recording layer 12 is not essential, and may be carried out optionally.

An example of manufacturing this kind of holographic recording medium will be described. At first, the recording layer 12 is integrally formed on one of the substrates 11 by a coating method such as spin coating. The outer spacer 13 and the inner spacer 14 are fixed on the outer peripheral portion and the inner peripheral portion on the surface of the substrate 11 on which the recording layer 12 has been provided; the spacers 13, 14 are fixed on the surfaces of the outer and inner peripheral grooves 21, 22 through adhesive layers made of the adhesive agent A. Further, adhesive layers are formed on the opposite surfaces of the spacers 13, 14 to which the other substrate 11 is to be fixed at a subsequent process; the adhesive agent A is applied to the surfaces of the outer and inner peripheral grooves 21, 22. The recording layer 12, the outer spacers 13, and the inner spacer 14 are sealed with the other substrate 11, for example, by a vacuum laminating method, such that no air gaps are formed between the substrate 11 and the recording layer 12. The adhesive agent A should not enter the interface between the substrate 11 and the recording layer 12 so as to obtain an appropriate optical performance,

As an alternative, another example of manufacturing the holographic recording medium will be described. At first, the recording layer 12 that has been previously manufactured is adhered to one of the pair of substrates 11 through an adhesive layer. The outer spacer 13 and the inner spacer 14 are fixed on the substrate 11 on which the recording layer 12 has been provided through adhesive layers made of the adhesive agent A. Further, the adhesive agent A is applied to the opposite surfaces of the spacers 13, 14 (i.e., surfaces of the outer and inner peripheral grooves 21, 22) and the opposite surface of the recording layer 12, to which surfaces the other substrate 11 is to be fixed at a subsequent process, so as to provide adhesive layers made of the adhesive agent A. The recording layer 12, the outer spacer 13, and the inner spacer 14 are bonded with the other substrate 11 such that no air gaps are formed between the substrate 11 and the recording layer 12. It is preferable that bonding between the spacers 13, 14 and the substrate 11 and the bonding between the substrate 11 and the recording layer 12 are carried out using the same adhesive agent.

The above manufacturing methods show preferable embodiments. However, the present invention is not limited to these methods, and other methods for manufacturing a holographic recording medium which comprises constituent elements according to the present invention may be conceived.

Next, description will be given of how the outer and inner peripheral grooves 21, 22 and the ring-shaped peripheral ridges 31, 32 of the holographic recording medium 1 according to this preferred embodiment work when compared with a conventional holographic recording medium.

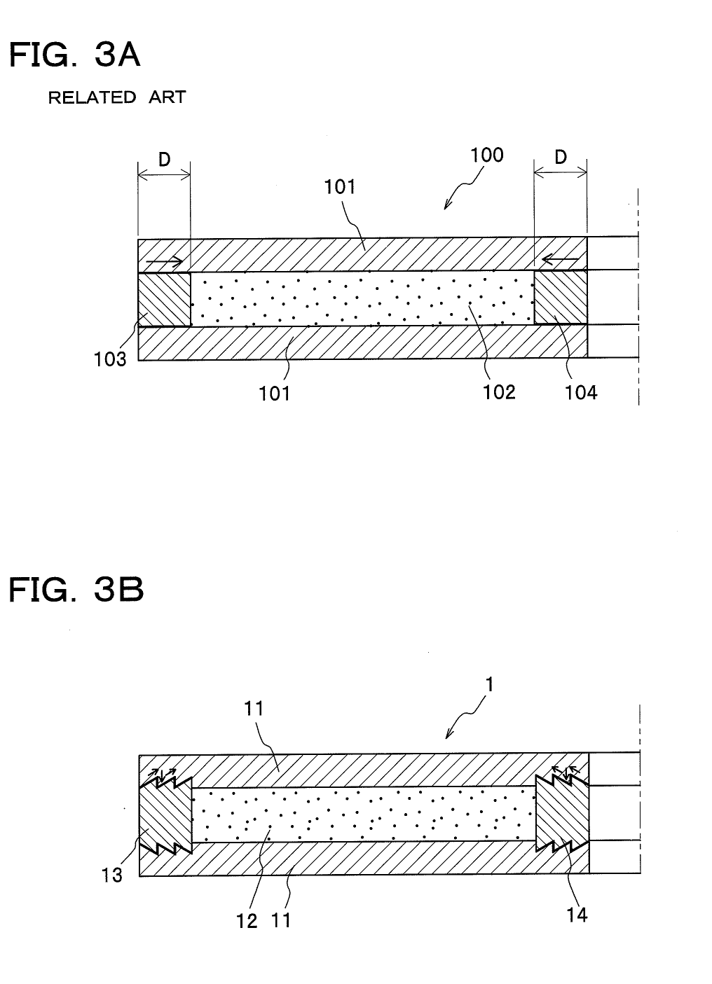

As best seen in FIG. 3A, a conventional holographic recording medium 100 includes a pair of substrates 101, a recording layer 102, an outer spacer 103, and an inner spacer 104, as with the holographic recording medium 1 according to the preferred embodiment of the invention. However, unlike the holographic recording medium 1, the conventional holographic recording medium 100 is manufactured such that the pair of substrates 101, the outer spacer 103, and the inner spacer 104 have flat surfaces at their mating faces. Therefore, during a long-term storage of the holographic recording medium 100, moisture gradually enters the recording layer 102 from the periphery of the holographic recording medium 100 through a linear passage to be formed between the substrates 101 and the spacers 103, 104. In other words, according to the conventional holographic recording medium 100, moisture can enter the recording layer 102 if the moisture travels by the distance D which corresponds to the width of the outer spacer 103 and the inner spacer 104.

In the holographic recording medium 1 according to the preferred embodiment of the invention, as best seen in FIG. 3B, during a long-term storage of the holographic recording medium 1, moisture gradually enters the recording layer 12 through a zigzag passage formed between the substrates 11 and the spacers 13, 14. In other words, according to this holographic recording medium 1, the possible moisture-permeation passage through which moisture, etc. enter the recording layer 12 becomes longer than the distance D of the conventional holographic recording medium 100 which corresponds to the width of the outer spacer 103 and the inner spacer 104. This makes it possible to store the holographic recording medium 1 for a longer period of time by an extent corresponding to the extended distance of the possible moisture-permeation passage.

When it is assumed that the angle of the tilted surfaces 21a, 22a is 30 degrees, the distance of the zigzag passage is as much as 3/\sqrt{3} times longer (approximately 1.7 times) than the possible moisture-permeation passage (i.e., distance D) of the conventional holographic recording medium 100. The distance of the zigzag passage can be increased as much as two times longer than the distance D if the angle of the tilted surfaces 21a, 22a increases further from 30 degrees. The amount of moisture permeation (i.e, amount of moisture that can permeate through the layer made of the adhesive agent A) can be calculated from the following formula:

Amount of moisture permeation=Moisture permeation coefficient×Sectional area of the passage (m²)×Time (s)×Partial pressure of water (Pa)÷Permeation distance (m)

Wherein “Moisture permeation coefficient” takes a constant value for each substance; for example, assuming that the moisture permeation coefficient of polycarbonate (material for the substrates 11) is 1, PET is 0.25, ABS resin is 0.75, PMMA (Acrylic resin) is 0.9, and polyethylene is 0.05-0.02. “Sectional area of the passage” indicates a sectional area perpendicular to the direction in which moisture permeates through. Comparing with the conventional holographic recording medium 100 and the holographic recording medium 1 according to the preferred embodiment of the invention, if the kind of adhesive agent A used, the sectional area of the passage, time, and the partial pressure of water are exactly the same, and the permeation distance of the holographic recording medium 1 is as much as two times longer than that of the conventional holographic recording medium 100, the amount of moisture permeation becomes ½ in the holographic recording medium 1 according to the preferred embodiment of the invention.

The moisture permeation coefficient of the substrate 11 can be lowered to a significantly smaller value by means of SiO deposition method or laminating of a barrier film. However, taking into consideration adhesiveness of the adhesive agent A, it is difficult to lower the moisture permeation coefficient of the adhesive agent A. According to the present invention, even if the conventional adhesive agent is used, the amount of moisture permeation can be easily lowered so that a holographic recording medium 1 which excels in moisture-proof property can be provided.

According to the present invention, not only moisture but also gas such as oxygen enters the recording layer 12 through the zigzag passage that provides an extended gas-entrance passage. This can restrict the influence of gas exerting on the recording layer 12 when compared with the structure of the conventional holographic recording medium 100.

According to the above preferred embodiment, the following advantages can be obtained:

(1) Because the cross-sectionally recessed portion and the corresponding cross-sectionally protruding portion are formed in and on the mating faces which are to be interengageable and bonded together with the adhesive agent A, moisture, etc. can hardly enter the recording layer 12. Therefore, the holographic recording medium 1 can be stored over an extended period of time even if the choice of the adhesive agent A is not so strictly made.

(2) Because the outer and inner peripheral grooves 21, 22 and the ring-shaped peripheral ridges 31, 32 of the holographic recording medium 1 are formed such that at least one ring-shaped peripheral groove and ridge are formed in and on the mating faces of the pair of substrates 11 and the spacers 13, 14, moisture, etc. entering the recording layer from any directions have to pass through the possible moisture-permeation passage which is bent by the cross-sectionally recessed portion 21, 22 and the corresponding cross-sectionally protruding portion 31. Therefore, an entry of moisture, etc. can be effectively restricted.

(3) Because the adhesive force is increased due to providing zigzag bonding surfaces, the bonding strength between the substrates 11 and the spacers 13, 14 can be improved.

Although the present invention has been described with reference to one preferred embodiment thereof, the present invention is not limited to this specific embodiment and various changes and modifications may be made without departing from the scope of the appended claims.

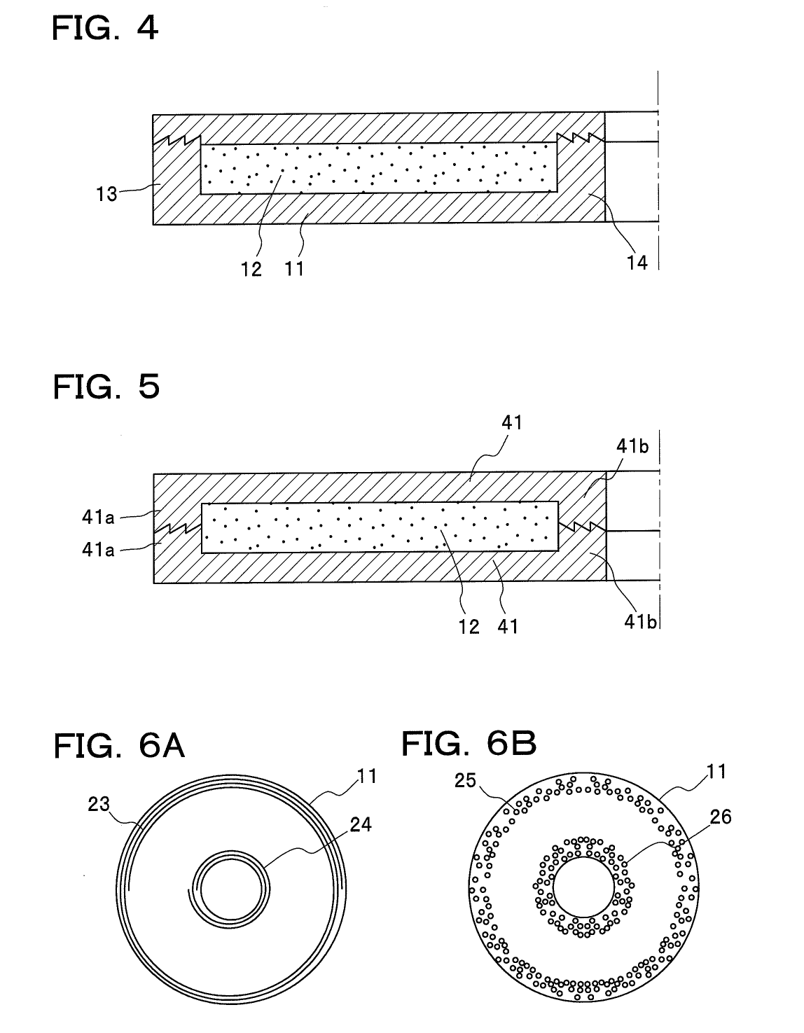

In the above preferred embodiment, the outer spacer 13 and the inner spacer 14 are provided separately from the pair of substrates 11. However, the present invention is not limited to this specific structure, and at least one of the outer spacer 13 and the inner spacer 14 may be integral with one of the substrates 11. For example, as seen in FIG. 4, the outer spacer 13 and the inner spacer 14 may be integrally formed with the lower substrate 11. This allows the number of possible moisture-permeation passages to be decreased, thereby enhancing the moisture-proof property.

In the above preferred embodiment, the outer spacer 13 and the inner spacer 14 are provided between the pair of substrates 11. However, the present invention is not limited to this specific structure. For example, as shown in FIG. 5, each one of the pair of substrates 41 has an outer peripheral protrusion 41a and an inner peripheral protrusion 41b extending from the outer peripheral portion and the inner peripheral portion thereof toward the other substrate 41 and surrounding the outer peripheral surface and the inner peripheral surface of the recording layer 12. Further, a cross-sectionally recessed portions and a corresponding cross-sectionally protruding portions are formed in and on the mating faces of one substrate 41 and the other substrate 41 at the outer peripheral protrusion 41a and the inner peripheral protrusion 41b so that the pair of substrates 41 are interengageable at their outer peripheral protrusions 41a and inner peripheral protrusions 41b, respectively and bonded together with an adhesive agent. According to this holographic recording medium, as with the holographic recording medium 1 as described above, the length of the possible moisture- and gas-permeation passage can be extended so that an entry of moisture, etc. can be restricted. Further, an entrance passage for moisture, etc. is formed only at the outer peripheral side and the inner peripheral side of the recording layer 12 between the pair of substrates 41. This can restrict an entry of moisture, etc. in a more effective manner.

In the above preferred embodiment, the peripheral grooves 21, 22 and the corresponding peripheral ridges 31, 32 of the holographic recording medium 1 are ring-shaped. However, the present invention is not limited to have these specific shapes of grooves and ridges. For example, as shown in FIG. 6A, a spiral-shaped outer peripheral groove 23 and a spiral-shaped inner peripheral groove 24 may be employed. As an alternative, as shown in FIG. 6B, a plurality of semi-spherical recesses 25, 26 may be arranged at random at the inner peripheral portion and the outer peripheral portion on the surface of the substrate 11. Although FIGS. 6A and 6B show grooves and recesses as an example of a cross-sectionally recessed portion, the corresponding cross-sectionally protruding portion can be readily formed so as to be interengageable with these grooves and recesses.

Although the substrate 11 is shaped like a disc having a center opening l la, the present invention is not limited to this specific configuration. The substrate may not be provided with an opening, so that a cross-sectionally recessed portion and a corresponding cross-sectionally protruding portion are formed in the mating faces around the outer peripheral surface of the recording layer. Further, instead of a disc-type holographic recording medium, the present invention may be applicable to a cartridge-type holographic recording medium in which the shape of the holographic recording medium is rectangular.

What is claimed is:

1. A holographic recording medium comprising:
a recording layer in which is recordable an interference pattern formed by interference of a plurality of laser beams;
a pair of substrates between which is arranged the recording layer; and
a spacer positioned between the substrates so as to cover an outer perimetrical surface of the recording layer,
wherein each substrate and the spacer have mating faces at which the substrate and the spacer are interengageable and bonded together with an adhesive agent, and wherein a cross-sectionally recessed portion is formed in the mating face of one of the substrate and the spacer, whereas a corresponding cross-sectionally protruding portion is formed on the mating face of the other one of the spacer and the substrate, allowing one mating face to be fitted into another.

2. A holographic recording medium according to claim 1, wherein the cross-sectionally recessed portion and the corresponding cross-sectionally protruding portion comprise at least one ring-shaped peripheral groove and at least one corresponding ridge formed in and on the mating faces of the substrate and the spacer along the outer perimetrical surface of the recording layer which is shaped like a disc.

3. A holographic recording medium according to claim 1, wherein the cross-sectionally recessed portion and the corresponding cross-sectionally protruding portion comprise a spiral groove and a corresponding spiral ridge formed in and on the mating faces of the substrate and the spacer along the outer perimetrical surface of the recording layer which is shaped like a disc.

4. A holographic recording medium according to claim 1, wherein the spacer is integral with one of the pair of substrates.

5. A holographic recording medium according to claim 1, further comprising an inner spacer positioned between the substrates so as to cover an inner peripheral surface of the recording layer which is shaped like a disc having a center opening, wherein each substrate and the inner spacer have mating faces at which the substrate and the inner spacer are interengageable and bonded together with an adhesive agent, and wherein a cross-sectionally recessed portion is formed in the mating face of one of the substrate and the inner spacer, whereas a corresponding cross-sectionally protruding portion is formed on the mating face of the other one of the inner spacer and the substrate, allowing one mating face to be fitted into another.

6. A holographic recording medium according to claim 5, wherein the cross-sectionally recessed portion and the corresponding cross-sectionally protruding portion formed in and on the mating faces of the substrate and the spacer comprise at least one ring-shaped peripheral groove and at least one corresponding ridge along the outer perimetrical surface of the recording layer, and wherein the cross-sectionally recessed portion and the corresponding cross-sectionally protruding portion formed in and on the mating faces of the substrate and the inner spacer comprise at least one ring-shaped peripheral groove and at least one corresponding ridge along the inner peripheral surface of the recording layer.

7. A holographic recording medium according to claim 5, wherein the cross-sectionally recessed portion and the corresponding cross-sectionally protruding portion formed in and on the mating faces of the substrate and the spacer comprise a spiral groove and a corresponding spiral ridge along the outer perimetrical surface of the recording layer, and wherein the cross-sectionally recessed portion and the corresponding cross-sectionally protruding portion formed in and on the mating faces of the substrate and the inner spacer comprise a spiral groove and a corresponding spiral ridge along the inner peripheral surface of the recording layer.

8. A holographic recording medium according to claim 5, wherein the spacer and the inner spacer are integral with one of the pair of substrates.

9. A holographic recording medium comprising:
a recording layer in which is recordable an interference pattern formed by interference of a plurality of laser beams; and
a pair of substrates between which is arranged the recording layer,
wherein each substrate has an outer perimetrical protrusion extending toward the other substrate and surrounding an outer perimetrical surface of the recording layer, and each outer perimetrical protrusion has a mating face at which the pair of substrates are interengageable and bonded together with an adhesive agent, and
wherein a cross-sectionally recessed portion is formed in the mating face of the outer perimetrical protrusion of one substrate, whereas a corresponding cross-sectionally protruding portion is formed on the mating face of the outer peripheral protrusion of the other substrate, allowing one mating face to be fitted into another.

10. A holographic recording medium according to claim 9, wherein the cross-sectionally recessed portion and the corresponding cross-sectionally protruding portion comprise at least one ring-shaped peripheral groove and at least one corresponding ridge formed in and on the mating faces of the pair of substrates along the outer perimetrical surface of the recording layer which is shaped like a disc.

11. A holographic recording medium according to claim 9, wherein the cross-sectionally recessed portion and the corresponding cross-sectionally protruding portion comprise a spiral groove and a corresponding spiral ridge formed in and on the mating faces of the pair of substrates along the outer perimetrical surface of the recording layer which is shaped like a disc.

12. A holographic recording medium according to claim 9, wherein each substrate has an inner peripheral protrusion extending toward the other substrate and surrounding an inner peripheral surface of the recording layer, and each inner peripheral protrusion has a mating face at which the pair of substrates are interengageable and bonded together with an adhesive agent, and wherein a cross-sectionally recessed portion is formed in the mating face of the inner peripheral protrusion of one substrate, whereas a corresponding cross-sectionally protruding portion is formed on the mating face of the inner peripheral protrusion of the other substrate, allowing one mating face to be fitted into another.

13. A holographic recording medium according to claim 12, wherein the cross-sectionally recessed portion and the corresponding cross-sectionally protruding portion at the outer perimetrical protrusions and at the inner peripheral protrusions of the pair of substrates comprise at least one ring-shaped peripheral groove and at least one corresponding ridge formed in and on the mating faces of the pair of substrates along the outer perimetrical surface and the inner peripheral surface of the recording layer which is shaped like a disc having a center opening.

14. A holographic recording medium according to claim 12, wherein the cross-sectionally recessed portion and the corresponding cross-sectionally protruding portion at the outer perimetrical protrusions and at the inner peripheral protrusions of the pair of substrates comprise a spiral groove and a corresponding spiral ridge formed in and on the mating faces of the pair of substrates along the outer perimetrical surface and the inner peripheral surface of the recording layer which is shaped like a disc having a center opening.
